(19) United States
(12) Patent Application Publication
(10) Pub. No.: US 2023/0288497 A1
(43) Pub. Date: Sep. 14, 2023

(54) CABLE MONITORING SYSTEM

(71) Applicant: Proserv UK Ltd, Westhill (GB)

(72) Inventors: Paul COOK, Great Yarmouth (GB); Preston CLARKE, Great Yarmouth (GB); Tore ERNTSEN, Great Yarmouth (GB)

(21) Appl. No.: 18/018,366

(22) PCT Filed: Jul. 27, 2021
(86) PCT No.: PCT/GB2021/051932

§ 371 Date: Jan. 27, 2023

(30) Foreign Application Priority Data
Jul. 29, 2020 (GB) 2011786.7

(51) Int. Cl. G01R 31/58

(52) U.S. Cl. CPC G01R 31/58

(57) ABSTRACT

A system for monitoring a cable, the system comprising: a memory storing processor readable instructions; and a processor arranged to read and execute instructions stored in said memory; wherein said processor readable instructions comprise instructions arranged to control the processor to: obtain data from a plurality of sensors, the sensors configured to detect a plurality of parameters of the cable, correlate the data associated with the cable parameters obtained from at least one or each of the sensors with data associated with the cable parameters obtained from at least one or each other of the sensors; analyse the correlated data to determine a presence of at least one operational abnormality in the cable.

### TECHNICAL FIELD

Described examples relate to a system and method for monitoring a cable, more particularly, a subsea cable.

### BACKGROUND

The offshore windfarm industry is still in its early life. There are many offshore wind farms sanctioned globally with the aim to increase energy generation from renewable sources. Offshore wind is currently the fastest growing sector for renewables.

Over these early years of production, one of the biggest challenges to the operators has been subsea cable early fatigue failure. Cable failures in offshore wind farms can lead to significant insurance claim costs. The failures are due to a number of reasons and subsea cable faults can result from issues during the design, manufacture, installation or operation phase.

Proposed new Offshore Windfarms have significant amounts of subsea cables, both array cables (connecting turbines to each other and to offshore substations) and export cables (connecting offshore substations to an onshore termination. Subsea cables may only account for 10% of the development cost of offshore wind farm, but may account for up to 80% of all offshore wind farm insurance claims. A significant number of insurance claims are attributed to cable failures, which indicates that these are a significant issue. Subsea cable repair or replacement is expensive and time consuming. In addition, factors such as weather, vessel and spare component availability, and the like, can delay repairs.

There is a continuing need to improve cable monitoring for subsea cables.

This background serves only to set a scene to allow a skilled reader to better appreciate the following description. Therefore, none of the above discussion should necessarily be taken as an acknowledgement that that discussion is part of the state of the art or is common general knowledge. One or more aspects/embodiments of the disclosure may or may not address one or more of the background issues.

### SUMMARY

In accordance with a first aspect of the invention, there is provided an system for monitoring a cable, the system comprising: a memory storing processor readable instructions; and a processor arranged to read and execute instructions stored in said memory; wherein said processor readable instructions comprise instructions arranged to control the processor to: obtain data from a plurality of sensors, the sensors configured to detect a plurality of parameters of the cable, correlate the data associated with the cable parameters obtained from at least one or each of the sensors with data associated with the cable parameters obtained from at least one or each other of the sensors; analyse the correlated data to determine a presence of at least one operational abnormality in the cable. Cable parameter(s) may relate to the condition of multiple factors of the cable.

This may have an advantage of providing a solution to excessive downtime caused by cable failure. The operator may be provided with full visibility of their cable assets and the cable monitoring system may enable condition-based maintenance, strategic maintenance planning and cost savings.

The processor may be configured to analyse the correlated data to determine a position of the at least one operational abnormality in the cable.

The processor may be configured to analyse the correlated data to determine a plurality of operational abnormalities in the cable.

The processor may be configured to correlate the data associated with the parameters to determine standard limits of the parameters of the cable. The cable parameters may be monitoring parameters. The processor may be configured to correlate the data associated with the monitoring parameters. Monitoring parameter(s) may relate to a measurable factor and/or specific measurement being utilised.

The processor may be configured to time correlate the data associated with the cable parameters.

The processor may be configured to compare the data and/or the correlated data with the determined standard limits of the parameters of the cable.

The determined standard limits of the cable parameters may comprise a cluster of normality created by plotting the cable parameters against each other whilst the cable is within an acceptable operating range. Monitoring parameters may be plotted against each other whilst the cable is within an acceptable operating range.

The cable parameters may comprise one or more of: voltage, electrical current, at least one parameter determined by distributed electrical sensing (DES), temperature, at least one parameter determined by distributed temperature sensing (DTS), at least one parameter determined by point temperature sensing, vibration, at least one parameter determined by distributed acoustic sensing (DAS), at least one parameter determined by distributed strain sensing (DSS), at least one parameter determined by distributed pressure sensing (DPS), at least one parameter determined by partial discharge (PD) and/or at least one parameter determined by line resonance analysis (LIRA). The cable parameters may be monitoring parameters.

The cable parameters may comprise derived parameters comprising resistance, inductance, conductance, capacitance, characteristic impedance, attenuation, phase velocity, effective permittivity, power, power quality, power factor, depth of burial, mechanical stress, electrical stress, strain, partial discharge, impedance, and/or days to failure. The cable parameters may be monitoring parameters.

The processor may be configured to provide real time indication of the operational abnormality.

The processor may be configured to detect potential faults in the cable.

The processor may be configured to provide predictive maintenance and/or operational recommendations based on fault detection and/or the determined at least one operational abnormality in the cable.

The processor may be configured to provide a first indication of normal operation, a second indication of a change in at least one parameter resulting in the operational abnormality, and a third indication of either a substantially rapid change in at least one parameter and/or a fault.

The processor may be configured to correlate and/or time correlate the data associated with the cable parameters using a machine learning process. The cable parameters may be monitoring parameters.

The processor may be configured to use supervised machine learning using historical operational data for training the system and/or unsupervised machine learning such that the system is trained heuristically.

The plurality of sensors may comprise passive sensors and/or an optical fibre.

The plurality of sensors may be configured to detect the plurality of cable parameters substantially simultaneously in a plurality of locations.

The system may comprise onshore and/or offshore monitoring stations.

The system may comprise at least one merger module for obtaining the data from the plurality of sensors and processing the data for sending to the processor.

The system may comprise at least one protocol convertor module for converting data from the plurality of sensors into at least one cohesive data stream for sending to the processor.

In accordance with a second aspect of the present invention, there is provided a method of monitoring a cable, the method comprising: obtaining data from a plurality of sensors, the sensors configured to detect a plurality of parameters of the cable, correlating the data associated with the cable parameters obtained from at least one or each of the sensors with data associated with the cable parameters obtained from at least one or each other sensors; analysing the correlated data to determine a presence of at least one operational abnormality in the cable.

The method may comprise analysing the correlated data to determine a position of the at least one operational abnormality in the cable.

The method may comprise analysing the correlated data to determine a plurality of operational abnormalities in the cable.

The method may comprise correlating the data associated with the cable parameters to determine standard limits of the parameters of the cable. The cable parameters may be monitoring parameters. The method may comprise correlating the data associated with the monitoring parameters.

In accordance with a third aspect of the present invention, there is provided a computer program comprising computer readable instructions configured to cause a computer to carry out a method as described above.

In accordance with a fourth aspect of the present invention, there is provided a computer readable medium carrying a computer program as described above.

### BRIEF DESCRIPTION OF THE FIGURES

FIG. 1 shows a schematic diagram of a wind farm with a cable monitoring system according to an embodiment of the present invention;

FIG. 2 shows a schematic diagram of system architecture of a cable monitoring system according to an embodiment of the present invention;

FIG. 3 shows an example graph of a cluster of normality for a cable monitoring system according to an embodiment of the present invention;

FIG. 4 shows a schematic diagram of a master monitoring station for a cable monitoring system according to an embodiment of the present invention;

FIG. 5 shows a schematic diagram of an offshore monitoring station for a cable monitoring system according to an embodiment of the present invention;

FIG. 6 shows a flowchart of the method of use of a cable monitoring system according to an embodiment of the present invention.

### DESCRIPTION OF SPECIFIC EMBODIMENTS

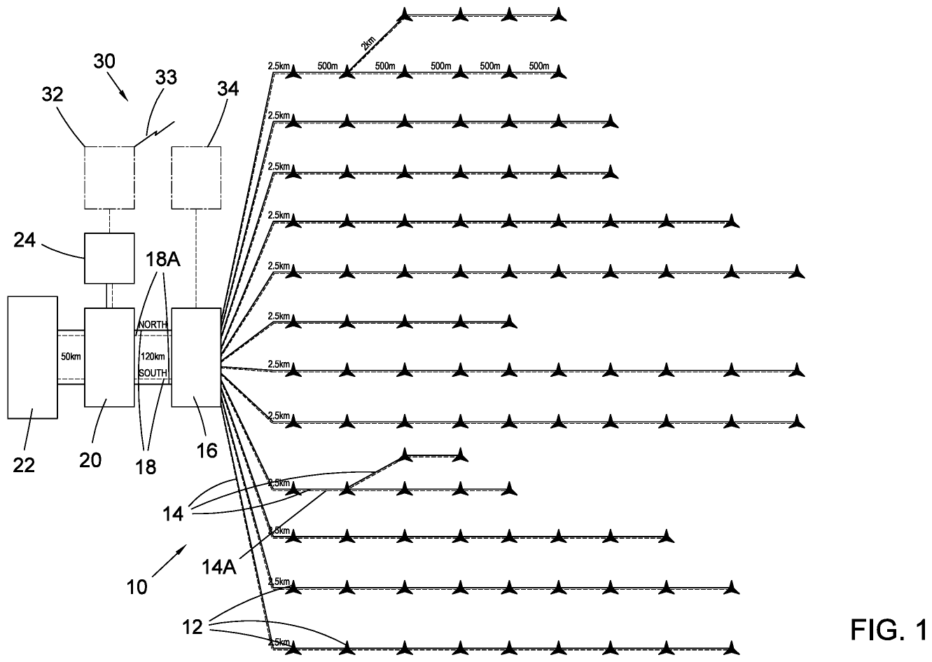

FIG. 1 shows a layout and topology of an embodiment of an offshore wind farm 10 with one hundred and two wind turbines 12. In this example, each turbine is rated at 7 MW capacity by way of example, but it will be appreciated that turbines having higher or lower rated capacity could be used. There are inter array cables 14 that connect the turbines 12 to each other and to an offshore substation 16. In this example, the array cables are rated at 66 kV but other cable ratings could be used. The array cables 14 comprise fibre optic cables 14A (shown in dashed lines) in addition to electrical transmission elements of the array cables 14. The vast majority of subsea cables in offshore wind generation feature an integral (or local) fibre optic cable. It will be appreciated that, in other embodiments, any number of turbines and array cables could be used.

Higher rated export cables 18 (e.g. 220 kV rated) connect the offshore substation 16 to an onshore termination 20 and to an onshore substation 22. Generally, the system comprises far fewer export cables 18 than array cables, and in this example two export cables 18 are provided, but other numbers of export cables 18 could be used. Generally only one or two export cables are used. Connected to the onshore termination 20 is an onshore operational control system 24, generally provided in a control centre. The export cables 18 comprise fibre optic cables 18A (shown in dashed lines) in addition to electrical transmission elements of the export cables 18. The distances of the cables specified are only examples. It will be appreciated that this is just an example wind farm layout and, in other embodiments, other layouts may be used.

A cable monitoring system 30 is provided, which includes a master monitoring station (MMS) 32. The MMS 32 may have remote network access 33 as depicted by the arrow. Also located with the MMS 32 is an operators workstation (OWS). Single or multiple operator workstations (OWS) may be provided externally to the MMS 32 in order to have local monitoring available to the operator with the need to work directly at the MMS 32. The cable monitoring system 30 also includes an offshore monitoring station (OMS) 34. The cable monitoring system 30 measures multiple parameters using sensing systems to provide an operator with a holistic way of monitoring inter array cables 14 and export cables 18, e.g. the condition of the cables 14, 18. The cable monitoring system 30 also provides for cable fault detection.

It will be appreciated that the cable monitoring system 30 is not limited to being used in a wind farm layout and, in other embodiments, may be used for monitoring cables in other situations. The cable monitoring system 30 may be installed onto a new (green) field development with third party sensors to obtain the required data. The cable monitoring system 30 may also be retrofitted onto an existing (brownfield) site using different third party sensor systems to meet the particular needs of the site. In embodiments, the cables may be subsea cables but it will be appreciated that, in other embodiments, the cables may be out of water.

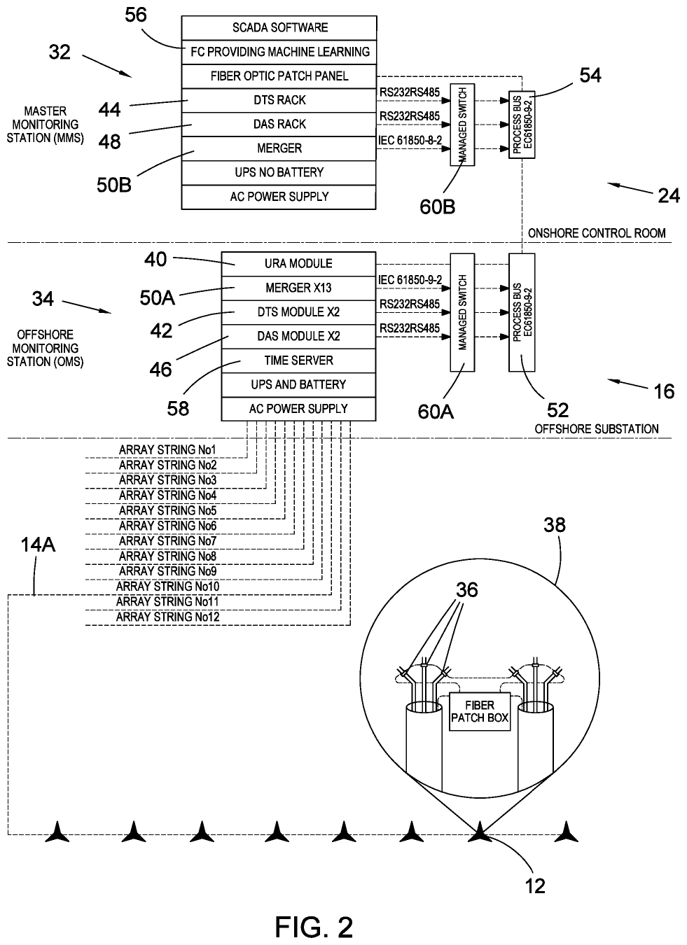

FIG. 2 shows the system architecture of the cable monitoring system 30. The MMS 32 is located in or with the onshore operational control centre and may be comprised in or configured to communicate with the onshore operational control system 24. The OMS 34 is located in the offshore substation 16. Fibre optic cables 14A may pass data from the turbines 12 to the MMS 32 and the OMS 34 for processing and analysis.

The cable monitoring system 30 is configured to obtain data from a plurality of sensors. In some embodiments, the sensors are in the form of sensor nodes 36 located in a wind turbine transition piece 38. The sensor nodes 36 are placed on each phase of the electrical cable on the input and output of the transition piece 38 of each turbine 12. The sensor nodes 36 measure parameters, e.g. point temperature and vibration, current (electrical), voltage and strain. Data is then output as an optical signal and propagated through the fibre optic cable 14A. At least some of the sensors could be, for example, electrical sensor nodes that comprise an electrical element that produces an electrical response indicative of the associated parameter. Alternatively or additionally, at least some of the sensors could comprise optical sensor nodes, e.g. sensors comprising fibre-Bragg gratings, Fabry-Perot etalons or other optical elements, that produce an optical response that is indicative of the associated parameter, such as strain and/or temperature. However, a range of sensor types could be used and are not limited to the above.

The sensors are configured to detect a plurality of parameters of the cable 14. A single sensor may detect a plurality of parameters to be fed back to the cable monitoring system 30. A plurality of sensors may each detect a single parameter to be fed back to the cable monitoring system 30. Parameters such as strain, temperature, insulation resistance and electrical loading are particularly useful to condition monitoring of subsea cables.

The cable monitoring system 30 monitors multiple parameters which are useful for the operators to know the condition of the cables 14, 18 in their field. These parameters are used to find relationships and trends in the data which allows for in-depth analysis, and ultimately prediction of cable faults. For simplicity, reference will be made to a single array cable 14 and fibre optic cable 14A but it will be appreciated that the features and method described will also be applicable to other array cables 14 and export cables 18.

The sensors may comprise passive sensors. The sensor technology may use optical fibre (the gold standard medium for low-loss communication), to enable long-distance and “power supply free” measurements of a wide range of electrical or mechanical parameters. By piggy-backing on existing fibre networks, this minimises the cost of installing, expanding or enhancing sensor coverage on power systems. By gathering many different measurements on a single fibre, protection and monitoring schemes may be made simpler and more efficient.

The sensor technology may simultaneously acquire measurements of many diverse parameters, notably voltage and current waveforms, from widely-spaced locations throughout a power network or item of plant. It does so passively, without traditional data rate limitations, and with minimal hardware. This results in flexible sensor array deployment, single-fibre interrogation, and an extremely rapid response-giving rise to a broad range of solutions to deliver improved and cost-effective instrumentation systems to the electrical power industries.

The optical sensing method uses passive sensors on the existing fibre optics 14A. The sensors 36 can be placed anywhere which needs to be measured, in this case the sensors 36 are placed on each phase of the cable 14A on the input and output of each turbine transition piece 38. In an array string of eight turbines 12, this equates to forty eight sensors 36 in the array including three sensors (not shown) at the offshore substation 16 to monitor the joint between the offshore substation 16 and the array cable 14. Sensors may also be placed on the export cable 18 at critical points or joints to monitor that part of the windfarms cable system. The cable monitoring system 30 covers faults in the GIS where the 220 kV export cable connects to the 400 kV transformer in the substation 16.

The OMS 34 comprises a LIRA module 40 that allows for the calculation of multiple parameters as will be explained later. The OMS 34 comprises a DTS (Distributed Temperature Sensing) module 42 and the MMS 32 comprises a DTS rack 44, each associated with distributed temperature sensors.

The OMS 34 comprises a DAS (Distributed Acoustic Sensing) module 46 and the MMS 32 comprises a DTS rack 48, each associated with distributed acoustic sensors.

Mergers are situated in the OMS 34 and/or the MMS 32 and can process the data from up to 50 sensors in a 100 km radius. The mergers 50A, 50B read the data from the fibre optics 14A inside the array cable 14 and turn that into useable data to be sent to an offshore substation process bus 52 (and onto an onshore process bus 54) for the merger 50A or straight to a computer system 56, such as a PC , for the merger 50B. As there are one hundred and two turbines 12 in the example field, it would be necessary to have thirteen offshore mergers 50A in the OMS 34 and another merger 50B in the MMS 32.

The OMS 34 may comprise a time server 58. The MMS 32 may comprise a fibre optic patch panel. Both the OMS 34 and the MMS 32 may comprise modules such as an Uninterruptable Power Supply (UPS) and battery, and an AC power supply. It will be appreciated that the OMS and MMS are not only limited to these modules and may have other modules. Furthermore, it will be appreciated that, in this embodiment, the cable monitoring system includes a MMS and an OMS but, in other embodiments, the cable monitoring system may have different or additional components to carry out the cable monitoring method.

Sensors may use different communications protocols. Programmed priorities can be used in order to keep the data time-synchronous in the transmission, which reduces the amount of data pre-processing that the PC will have to perform.

An onshore managed switch/protocol convertor 60A is used between the offshore substation process bus 52 and the offshore modules. An offshore managed switch/protocol convertor 60B is used between the offshore onshore process bus 54 and the onshore modules. Different protocols mean that a protocol convertor is necessary before the data goes to one process bus. The purpose of the switches/proctol convertors 60A, 60B is to convert different data sets to one cohesive data stream which can transmit through a single process bus. A managed switch will help connecting/managing the data traffic. A managed switch holds the capability to compute data streams and configure them into the necessary interface to all be published to the same process bus in order for the signal to be sent to the MMS 32.

The cable monitoring system 30 comprises the computer system 56, such as the PC, but could in principle could comprise any suitable form of local, network, cloud based or distributed computing resource. The computer system 56 comprises a memory storing processor readable instructions and a processor arranged to read and execute instructions stored in the memory. The processor readable instructions comprise instructions arranged to control the processor to obtain, correlate and analyse data from the sensors.

The cable monitoring system 30 uses a cable monitoring method utilising a plurality of monitoring parameters (e.g. DTS, DAS, LIRA (Line Resonance Analysis), DES (Distributed Electrical Sensing)). The multiple monitoring parameters comprise data that is individually collected, which is then processed by software to correlate the data for different parameters. The cable monitoring system 30 correlates the data associated with the parameters obtained from at least one or each of the sensors with data associated with the parameters obtained from at least one or each other of the sensors.

The correlation of the data associated with the parameters determines standard limits of the array cable 14. That is, it defines the normal working parameters of the array cable 14 (i.e. a cluster (or cloud) of normality).

The cable monitoring system 30 analyses the correlated data to determine at least one operational abnormality in the array cable 14. That is, the presence of the operational abnormality in the array cable 14. The position of the operational abnormality in the array cable 14 may also be determined. The processor is configured to provide real time indication of the operational abnormality. The real time aspect relates to data that is being collected and analysed for immediate use, so e.g. within seconds or less all data from the cables will be available to the operator on the front end system. An operational abnormality may be defined as a variation in a parameter or parameter interaction that indicates a change to the normal operation of the cable.

The processor of the cable monitoring system 30 is configured to time correlate the data associated with the parameters. More particularly, the processor is configured to time correlate the data associated with temperature and current. This enables real-time dynamic line rating.

With the continuous collection and correlation of operational data, the software is configured to understand what is normal (i.e. within standard limits) and what can be classed as abnormalities. In embodiments, this is carried out through a Machine Learning (ML) process. The processor is configured to correlate and/or time correlate the data using the ML process.

Machine Learning (ML) is a subcategory of artificial intelligence (Al) where a computer (PC) adjusts algorithms to find trends and normalities within the parameters. At first, the software implemented by the processor can be ‘trained’ via supervised machine learning (e.g. using historical operational data) but once that training is complete the software is configured to learn heuristically using unsupervised machine learning.

With the use of historical data, a cluster of normality can be developed where the parameters can vary within that cluster without the system finding a problem. However when a parameter (or parameters) strays outside of normality the software implemented by the processor is configured to determine that there is an issue with the array cable 14. This is the supervised learning part of the ‘training’.

The system “learns” more with more data being fed through it, meaning that the system becomes more defined and more individualised to the particular asset the longer that is in operation. This is particularly useful as ageing is a major cause of cable fault and therefore the ML aspect helps to combat this process. This is the unsupervised learning.

The cable monitoring system 30 may obtain data related to a parameter determined by Distributed Electrical Sensing (DES). One of the parameters of the cable 14 that may be measured is voltage. Voltage is measured using a sensor (e.g. sensor node 36) attached to the cable 14 and arranged such that the sensor is configured to use the fibre optic cable 14A to relay information back to the substation 16 where it is analysed.

Another parameter of the array cable 14 that may be measured is current (electrical). Resistance to high current is a principle cause of overheating and therefore the monitoring of current is valuable to the holistic view. Current is measured at critical points along the array cable 14 and the export cable 18, typically at least at the substation 16 and at transition pieces 38. These measurements may be made by the sensor nodes 36.

Another parameter of the array cable 14 that may be measured is associated with (determined by) Line Resonance Analysis (LIRA). LIRA measures a wide band impedance spectrum. Impedance, as it measures resistance to current, gives an indication of any damage to the array cable 14 because if the array cable 14 is damaged then the internal circuit resistance will increase at that point. From this reading and further analysis, multiple parameters may be determined which are useful to an operator in order to know the condition of the array cable 14. LIRA is also useful in producing an initial cable fingerprint to allow for quick recognition of when a fault occurs.

The OMS 34 comprises the LIRA module 40 that allows for the calculation of multiple parameters such as resistance, inductance, conductance, capacitance, characteristic impedance, attenuation, phase velocity & effective permittivity. With these parameters it is possible to detect and locate moisture ingress, mechanical damage, electrical treeing caused by partial discharge, temperature and radiation damage with respect to the array cable 14.

The cable monitoring system 30 may also derive further parameters (i.e. derived parameters) from the measured parameters. For example, power is calculated using voltage and current readings from sensors, or simply current if the resistance of the conductor is known. Power quality can be deduced from current readings on sensors, the precise current measurements show harmonics which can indicate problems with the power quality by analysing the amplitudes of the harmonics. The calculation of this parameter will, over time, provide data which can inform the operator of certain issues within the field. Monitoring power quality may identify where energy loss is present and assist with predictive maintenance.

In addition, power factor may be derived. Power factor is the ratio of the actual electrical power to the r.m.s values of current and voltage. The difference between the values is caused by reactance in the circuit and represents unwanted power that is dissipated. The circuit should have a power factor of 1 if it is 100% efficient. The below equations represent the relationship between these values where Q is the reactive power, S is the apparent power, θ is the power factor, and P is the real power.

Q=P tan(cos⁻¹(θ))

θ=cos(tan⁻¹(Q/P)

cos θ=P/S

In some cases, traditional subsea cable condition monitoring primarily utilises Distributed Acoustic Sensing (DAS). DAS systems use fibre optic cables to provide distributed strain sensing. Also in DAS, the optical fibre cable becomes the sensing element and measurements are made, and in part processed, using an attached optoelectronic device.

In some cases, traditional subsea cable condition monitoring primarily utilises Distributed Temperature Sensing (DTS) techniques. DTS systems are optoelectronic devices which measure temperatures by means of optical fibres functioning as linear sensors within the cable. Temperatures are recorded along the optical sensor cable, not at points but as a continuous profile. Typically, the DTS system can locate the temperature to a spatial resolution of 1 m with accuracy to within ±1° C. at a resolution of 0.01° C. Whilst you can derive certain diagnostics from DTS, this does not give the operator the full characteristics and visibility of the cable.

In cases where DAS and DTS are present, the parameters may be only working in silos with no correlation between the two monitoring parameters.

In contrast, the cable monitoring system 30 correlates some or all of the monitored parameters so that the effects between e.g. temperature, strain and other characteristics may be understood. The cable monitoring system 30 may use data from passive sensors including the optical fibre 14A itself.

The cable monitoring system 30 may obtain data related to the parameter determined by Distributed Acoustic Sensing (DAS). DAS systems are utilised to measure the vibration within cables, allowing for the effect of seismic events, natural movement of the cable and the internal cable integrity to be closely monitored to a precise degree of accuracy. This requires a special interrogator unit, which connects to the fibre optics 14A and then analyses the data to identify abnormalities. DAS systems use optoelectronic instruments, which measure acoustic interactions along the length of a standard fibre optic cable. This is optimised on a SM (single mode) fibre optic cable as a MM (multi-mode) fibre optic cable will induce more noise and disrupt the signal. As the pulse of light is propagated along the optical fibre localised acoustic energy causes tiny strain events within the fibre which causes backscatter of the light. Knowledge of the propagation speed allows for accurate mapping of backscatter events. Only once the pulse has reached the end of the fibre and the backscatter has returned to the interrogator can a subsequent laser pulse be introduced without risk of interference.

A further parameter is Strain (or Stress). This could be measured using the DAS module 46, by way of example, but other types strain and/or stress sensors could be used. Stress can either be tensional or compressional. Physical tension or compression of the cable causes mechanical stress; this can cause defects in the insulation or sheathing which will weaken the cable and reduce its effectiveness, this eventually leads to degradation and ultimately failure. Electrical stress is also a factor in cables and is applied to the insulating material, high electrical stress leads to the degradation of the insulator from the inside out which is difficult to detect without a sensor directly monitoring it. It leads to phenomenon such as water treeing and partial discharge.

In embodiments, the cable monitoring system 30 may obtain data related to the parameter determined by distributed strain sensing (DSS).

In embodiments, the cable monitoring system 30 may obtain data related to the parameter determined by partial discharge (PD).

In embodiments, the cable monitoring system 30 may obtain data related to the parameter determined by distributed pressure sensing (DPS).

The cable monitoring system 30 may obtain data related to the parameter determined by Distributed Temperature Sensing (DTS). By using the fibre optic cable 14A in order to measure the temperature at all points simultaneously, DTS allows for real-time analysis of the temperature within the array cable 14. This allows for the system to monitor and record the temperature along the length of the array cable 14. Measurements can be, for example, accurate up to 0.01° Celsius and accurate up to 5 m spatial resolution along the fibre. DTS systems use optoelectronic instruments, which measure the reflections along the length of a standard fibre optic cable. This is optimised on a MM (multi-mode) fibre optic cable. The forward propagating light has 2 distinct wavelengths called the “Stokes” and “Anti Stokes” light. Stokes light is not dependant on temperature whereas Anti Stokes light is strongly dependant on temperature and so the temperature profile within the optical fibre is calculated taking the ratio of the amplitude of these wavelengths. The spatial localisation of the backscattered light is determined through the knowledge of the propagation speed through the fibre.

A further parameter may be determined by Point Temperature Sensing. This is measured using passive temperature sensors installed in the transition pieces 38 of the turbines. Point temperature may be monitored at the cable termination. DTS systems typically bypass the array cable termination points where cables are more prone to overheating and therefore it is important to install temperature sensors at these points. A further parameter is Depth of Burial. Using DTS data, any temperature changes inside the array cable 14 can be used to calculate the depth of burial. This parameter may require outside knowledge such as geotechnical characteristics in order to accurately calculate the depth of burial, and should factor in the heat generated by the cable itself, the thermal properties of the soil and the temperature at the bottom of the ocean/sea. Once all of these parameters are known, analysis of the DTS readings can begin to give readings accurate up to 300 mm of the depth of burial.

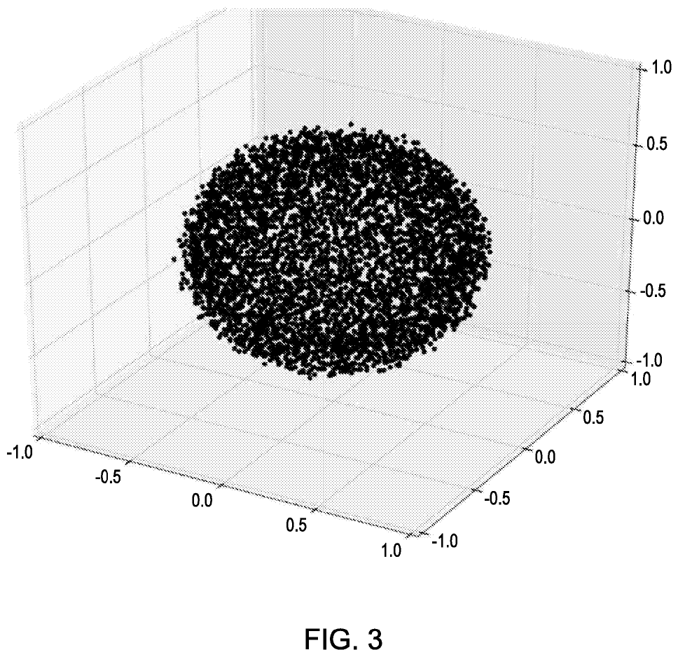

FIG. 3 shows an example graph of a cluster of normality. The determined standard limits of the parameters comprise the cluster of normality. The cluster of normality may be created by plotting the parameters against each other. Multi-dimensional analysis may be used with each type of sensor data (i.e. each parameter) being a different dimension. It is possible to find a cluster where the data is indicating normal operation within it (i.e. the cable is within an acceptable operating range). FIG. 3 demonstrates how data points can construct a cluster or cloud, this cluster represents normal variation of parameters wherein the interaction of parameters is also taken into account. That is, the use of the cluster of normality takes into account correlations between parameters and thereby accounts for situations where values of a parameter that are considered normal could change when the values of other correlated parameters change.

The cluster of normality allows for normal fluctuations in operational parameters to be accounted for, therefore making the prediction system more accurate in detecting faults as there will be fewer false alarms.

As an example, one or more parameters may be changing and moving towards standard limits which have been determined for those specific parameters. In one case, a parameter may reach or exceed that limit which results in a data point moving out of the cluster of normality. The cable monitoring system 30 may then provide a warning. In another case, one parameter itself may not reach the limit but, at the same time, another parameter may also be moving towards a standard limit which has been determined for the other parameter. Combining the movement of both these parameters together may result in a data point moving outside of the cluster of normality. The cable monitoring system 30 may then provide a warning. It will be appreciated that this method may be used for correlated data from multiple parameters, e.g. more than just two parameters as in this example.

The cable monitoring system 30 is configured to detect potential faults in the array cable 14. Using some or all of the measured and derived parameters in combination it is possible to predict the number of days it will take for a failure to occur. This allows for guidance on how to operate the system to be provided by the cable monitoring system 30. If the days to failure are low, the cable monitoring system 30 is configured to provide advisories that, if actioned, could increase time until failure, or if the days to failure are high and the system is nearing the end of its lifetime then it could aid with decision-making when repowering.

The cable monitoring system 30 may comprise hardware and software for monitoring inter array cables 14 and export cables 18 holistically. This enables cable integrity data to be collected through various monitoring parameters, the data can then be processed via algorithms to determine the condition of the cable real time and also pre-empt potential future failures. Based on the data, the system may then give operational recommendations to potentially mitigate a fault from occurring, thus increasing up time and protecting the integrity of the cable assets.

Within the software, there may be an integrated traffic light warning system. This is a simple but intuitive warning system which gives a certain level of alarm warning dependant on the detected cable issue.

A green warning denotes normal operation and healthy condition. Green may indicate that no action is necessary. That is, the processor is configured to provide a first indication of normal operation. An amber warning denotes a change in operational parameters and that parameters are outside of the cluster of normality. That is, a second indication of a change in at least one parameter resulting in the operational abnormality. The amber warning alarm does not mean that production is down, and gives the operator visibility of a fault occurring with the opportunity to change operational parameters to mitigate the fault. Amber may indicate that action is necessary to prevent a future fault. A red warning signal denotes either a rapid change in operational parameters or a fault resulting in production down time. Red may equate to a fault having been found. That is, a third indication of either a substantially rapid change in at least one parameter and/or a fault.

There may be services related to the amber and red warning signals. The operator can call upon the services for further investigation of the cable condition, or the involvement of cable specialists to complete cable analysis. Further to this, the cable monitoring system 30 can optionally be configured to provide an added reporting service, e.g. on a periodic basis, so the operator can keep track of cable integrity on a regular basis. This reporting function can either be a standard report derived directly from the software of the system, or a detailed analysis report from independent cable specialists based on data from the software of the system. The processor is configured to provide predictive maintenance and/or operational recommendations based on the fault detection.

By collating and using data in a smart way with the incorporation of machine learning software, the cable monitoring system 30 can provide a solution to excessive downtime caused by cable failure.

Advantages of the cable monitoring system 30 may include providing centralised measurements without additional telecommunications hardware: all measurements are made available at a single location without the need for dedicated communications systems. That is, the fibre is utilised to both measure and communicate the data.

In addition, there are multiple measurements of diverse parameters. For example, voltage, current, temperature and vibration can be measured using remote non-powered sensors. Preferably, as a minimum, each monitoring parameter should have its own designated fibre. Using the OMS 34, the array cable data (DTS,DAS, merger etc.) may be collated and transmitted to the MMS 32 using one data connection such that the different non-powered sensors can all be interrogated via the common data connection from the OMS 34 (although, in other examples, a plurality of data connections could be used).

Furthermore, interrogation of large, wide-area sensor networks may be provided. Unlike other measurement technologies, which utilise digital communications, this technology can scale up the number of sensors and the area covered without any significant impact on network complexity or measurement bandwidth.

The plurality of sensors may be configured to detect the plurality of parameters substantially simultaneously in a plurality of locations. There is fixed and known measurement latency, which can be factored in such that all measurements are in synchronism (e.g. with fixed and known latency of approximately 5 μs per km).

The cable monitoring system 30 can be compatible with the latest standards. For example, measurements can be made available in standardised sampled value formats (IEC 61850-9-2) or bespoke protocols.

Continuous monitoring of cables may help to prevent or pre-empt certain failures and allow for better planning of offshore remedial works (scheduling & availability of vessels, personnel and spare parts).

Previous typical monitoring methods are limited to the raw data which then must be interrogated by an independent cable specialist to generate reports so that the information can be understood.

Active cable monitoring along with early prediction would be an advantage to the operators in maintenance planning to avoid catastrophic failures. A system that can offer real-time monitoring and prediction of failures would benefit the operators. This would allow them to be proactive in the operation and maintenance of their assets, avoiding downtime.

The operator may be provided with full visibility of their cable assets and the cable monitoring system 30 enables condition-based maintenance, strategic maintenance planning and cost savings in both OPEX phases of the project life. There may be operations gains and OPEX savings. Furthermore, there may be reduced in service faults, income loss, repair costs, and capital cost.

The cable monitoring system 30 provides user friendly holistic integrated systems that can track the status of subsea cables (major component) within the wind plant to inform O&M decisions. The system will also increase and improve the use of data analytics and big data management to increase offshore wind reliability.

The cable monitoring system 30 is of an open nature, which will allow new technologies to be added or improved as they come to market, so ensuring a future-proofed and flexible system to end users.

The cable monitoring system 30 comprises a number of major hardware sub-components.

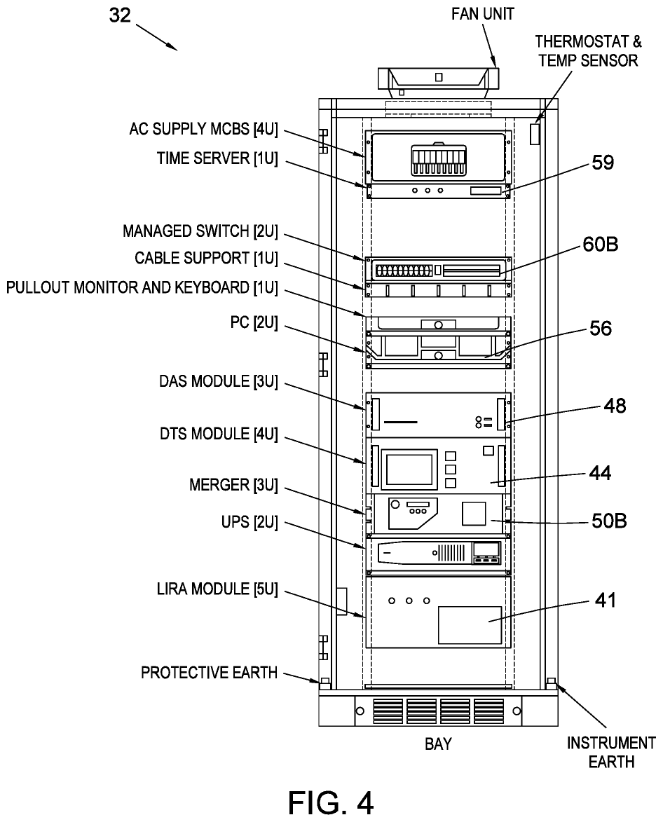

FIG. 4 shows one possible example of the master monitoring station (MMS) 32. The MMS 32 will house a number of sub components and interconnections for data collection and processing of field array cables 14 and export cables 18. The MMS 32 is onshore in the control centre. The MMS panel is a modular design constructed of a standard 19″ instrument panel. The MMS 32 power requirements can be configured according to the required level of redundancy. It can accept a single or dual AC supply. The Uninterruptable Power Supply (UPS) can be contained in the MMS 32 to provide hours of back up.

There is a single merger 50B in the MMS 32 to collect measurements from the export cable 18. This may be considered to be a Distributed Electrical Sensing Module. Measurements taken from the end of the cable closest to the onshore substation 22 will be connected to a merger in the OMS 34.

The DTS module 44 will interrogate the fibre optics in the export cable 18 and measure the distributed temperature in the export cable 18. This is in both the MMS 32 and OMS 34 to measure the length of the export cable 18 from both ends. The system can utilise any existing DTS unit on a brownfield site or any other unit. There may be no sensors required to be installed, just a rack mounted interrogation unit which when connected to the fibre optics within the submarine cable, propagates an optoelectronic signal through the fibre to measure temperature. This unit when located in the OMS 34 publishes the data to the substations process bus 52, while in the MMS 32 the data goes straight to the computer system 56.

The DAS module 48 is configured to measure the distributed acoustics of the export cable 18 from an interrogator unit in the MMS 32 and one in the OMS 34 to measure the length of the export cable 18 from both ends. The system can utilise any existing DAS unit on a brownfield site or any other unit. There may be no sensors required to be installed, just a rack mounted interrogation unit which when connected to the fibre optics within the submarine cable, propagates an optoelectronic signal through the fibre to measure the parameter. This unit when located in the OMS 34 publishes the data to the substations process bus 52. In the MMS 32, the data goes straight to the computer system 56.

In this embodiment, there is a LIRA module 41 in the MMS 32. The LIRA module 41 measures the resonance of the export cables 18 from an interrogator unit within the MMS 32.

In this embodiment, there is a time server 59 in the MMS 32. In the eventuality that the cable monitoring system 30 requires its own time synchronisation method, the time server 59 is installed. It is also possible to utilise one that already exists as part of the data processing already undertaken on a field.

An important part in the machine learning capable computer system 56 is multiple GPUs with high processing capabilities. Without this, the hardware may not be able to keep up with the data processing speeds that the software demands.

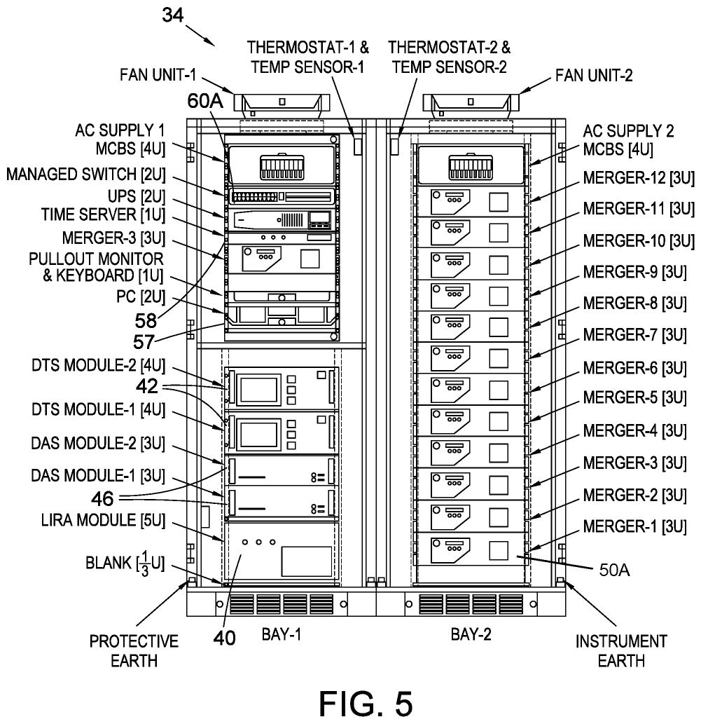

FIG. 5 shows an example of the offshore monitoring station (OMS) 34. In this example, the OMS 34 houses rack mounted equipment to gather the data outlined by the parameters. The OMS 34 in this example comprises a patch panel, interrogator machines and multiple mergers 50A within the station which publish the data to the process bus 52 to be sent to the MMS 32. The OMS panel is a modular design constructed of a standard 19″ instrument panel. It is a double width panel to hold the hardware required.

The OMS 34 power requirements can be configured according to the required level of redundancy. The OMS 34 can accept a single or dual AC supply and additionally a UPS can be fitted if greater availability is required.

The mergers 50A in the OMS 34 are responsible for collecting sensor data from the sensors in the array and the near end of the export cable 18. They may be considered to be a Distributed Electrical Sensing Module. In this specific, example, thirteen mergers 50A will be needed in the rack to ensure total system coverage. The mergers 50A connect through the process bus and send on the data to be received by the MMS 32.

There are two DTS modules 42. In use, the DTS module 42 interrogate the fibre optics 14A in the cable 14 and measure the distributed temperature in the array cables 14 and export cables 18. The interrogator unit in this example uses the fibre optics 14A for both sensing and transmission of data via the process bus 52. Measurement timings can be chosen to suit the needs over 10 s, and 4, 8, and 16 channel multiplexer modules are available.

The OMS 32 comprises two DAS modules 46 for measuring the distributed acoustics of the array cable 14. In this embodiment, the OMS 34 includes a computer system 57, e.g. for processing and analysing data.

The LIRA module 40 in the OMS 32 is configured to monitor the array cables 14, collecting data to then be analysed by the cable monitoring system 30.

The OMS 34 comprises a Managed Switch/Protocol Converter 60A. The sensors may use different communications protocols. For example, IEC 61850 may be selected for use with cable monitoring system 30. The OMS 34 can be programmed with priorities in order to keep the data time-synchronous in the transmission, which reduces the amount of data pre-processing which the computer system 57 will have to perform.

The sensors are arranged to publish data to the offshore substation process bus 52. The MMS 32 can then access the published data from the onshore control system 24. Many different protocols can be supported going to the process bus 52 and can be integrated into the MMS 32 in order to complete data analysis.

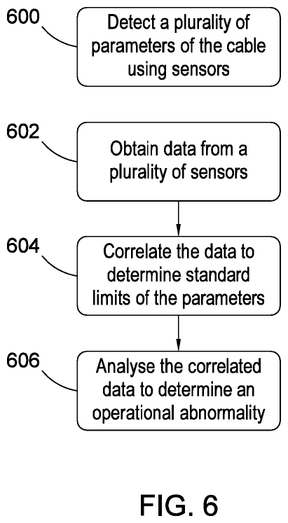

FIG. 6 shows a flow diagram of a method of using the cable monitoring system 30. In step 600, a plurality of sensors 36 detect a plurality of different parameters of the array cable 14. The sensors may be active or passive. The sensors 36 may provide the data in real time and simultaneously. In step 602, the processor obtains data from the plurality of sensors 36.

In step 604, the processor correlates the data to determine standard limits of the parameters associated with the array cable 14. The standard limits define normal working parameters of the array cable 14. The correlation may include time correlation. The data associated with the parameters obtained from at least one or each of the sensors 36 is correlated with data associated with the parameters obtained from at least one or each other sensors 36. This correlation and/or analysis may be carried out in a supervised or an unsupervised machine learning process.

In step 606, the correlated data is analysed to determine an operational abnormality of the array cable 14. This information may then be used for fault detection or potential faults in the array cable 14, a real time indication of the operational abnormality, a warning to the operator, to provide predictive maintenance and/or operational recommendations based on the fault detection.

The skilled person will be able to envisage further embodiments of the disclosure without departing from the scope of the appended claims.

1. A system for monitoring a cable, the system comprising:
a memory storing processor readable instructions; and
a processor arranged to read and execute instructions stored in said memory;
wherein said processor readable instructions comprise instructions arranged to control the processor to:
obtain data from a plurality of sensors, the sensors configured to detect a plurality of parameters of the cable,
correlate the data associated with the cable parameters obtained from at least one or each of the sensors with data associated with the cable parameters obtained from at least one or each other of the sensors;
analyse the correlated data to determine a presence of at least one operational abnormality in the cable.

2. The system of claim 1, wherein the processor is configured to analyse the correlated data to determine a position of the at least one operational abnormality in the cable.

3. The system of claim 1, wherein the processor is configured to analyse the correlated data to determine a plurality of operational abnormalities in the cable.

4. The system of claim 1, wherein the processor is configured to correlate the data associated with the cable parameters to determine standard limits of the parameters of the cable.

5. The system of claim 4, wherein the processor is configured to time correlate the data associated with the cable parameters.

6. The system of claim 4, wherein the processor is configured to compare the data and/or the correlated data with the determined standard limits of the parameters of the cable.

7. The system of claim 4, wherein the determined standard limits of the cable parameters comprise a cluster of normality created by plotting the cable parameters against each other whilst the cable is within an acceptable operating range.

8. The system of claim 1, wherein the cable parameters comprise one or more of: voltage, electrical current, at least one parameter determined by distributed electrical sensing (DES), temperature, at least one parameter determined by distributed temperature sensing (DTS), at least one parameter determined by point temperature sensing, vibration, at least one parameter determined by distributed acoustic sensing (DAS), at least one parameter determined by distributed strain sensing (DSS), at least one parameter determined by distributed pressure sensing (DPS), at least one parameter determined by partial discharge (PD) and/or at least one parameter determined by line resonance analysis (LIRA).

9. The system of claim 1, wherein the cable parameters comprise derived parameters comprising resistance, inductance, conductance, capacitance, characteristic impedance, attenuation, phase velocity, effective permittivity, power, power quality, power factor, depth of burial, mechanical stress, electrical stress, strain, partial discharge, impedance, and/or days to failure.

10. The system of claim 1, wherein the processor is configured to provide real time indication of the operational abnormality.

11. The system of claim 1, wherein the processor is configured to detect potential faults in the cable.

12. The system of claim 1, wherein the processor is configured to provide predictive maintenance and/or operational recommendations based on fault detection and/or the determined at least one operational abnormality in the cable.

13. The system of claim 1, wherein the processor is configured to provide a first indication of normal operation, a second indication of a change in at least one parameter resulting in the operational abnormality, and a third indication of either a substantially rapid change in at least one parameter and/or a fault.

14. The system claim 1, wherein the processor is configured to correlate and/or time correlate the data associated with the cable parameters using a machine learning process.

15. The system of claim 14, wherein the processor is configured to use supervised machine learning using historical operational data for training the system and/or unsupervised machine learning such that the system is trained heuristically.

16. The system of claim 1, wherein the plurality of sensors comprise passive sensors and/or an optical fibre.

17. The system of claim 1, wherein the plurality of sensors are configured to detect the plurality of cable parameters substantially simultaneously in a plurality of locations.

18. The system of claim 1, wherein the system comprises onshore and/or offshore monitoring stations.

19. The system of claim 1, wherein the system comprises at least one merger module for obtaining the data from the plurality of sensors and processing the data for sending to the processor.

20. The system of claim 1, wherein the system comprises at least one protocol convertor module for converting data from the plurality of sensors into at least one cohesive data stream for sending to the processor.

21. A method of monitoring a cable, the method comprising:
obtaining data from a plurality of sensors, the sensors configured to detect a plurality of parameters of the cable,
correlating the data associated with the cable parameters obtained from at least one or each of the sensors with data associated with the cable parameters obtained from at least one or each other sensors;
analysing the correlated data to determine a presence of at least one operational abnormality in the cable.

22. The method of claim 21, the method comprising correlating the data associated with the cable parameters to determine standard limits of the parameters of the cable.

23. (canceled)

24. A non-transient computer readable medium carrying computer readable instructions configured to cause a computer to carry out a method according to claim 21.
